(19) United States
(12) Patent Application Publication
(10) Pub. No.: US 2024/0390951 A1
(43) Pub. Date: Nov. 28, 2024

(54) SUBSTRATE CLEANING DEVICE AND SUBSTRATE CLEANING METHOD

(71) Applicant: SCREEN HOLDINGS CO., LTD., Kyoto (JP)

(72) Inventors: Takuma TAKAHASHI, Kyoto-shi, Kyoto (JP); Kazuki NAKAMURA, Kyoto-shi, Kyoto (JP)

(21) Appl. No.: 18/694,381

(22) PCT Filed: Jun. 29, 2022
(86) PCT No.: PCT/JP2022/025892

§ 371 Date: Mar. 21, 2024

(30) Foreign Application Priority Data
Sep. 22, 2021 (JP) 2021-154408

(51) Int. Cl. B08B 1/36; B08B 1/12

(52) U.S. Cl. CPC B08B 1/36; B08B 1/12

(57) ABSTRACT

A substrate cleaning device includes a pair of upper holding devices that hold an outer peripheral end of a substrate, a lower-surface brush that comes into contact with a lower surface of the substrate to clean the lower surface of the substrate and a control device that changes an uplift force for uplifting the lower-surface brush in a period during which the lower-surface brush cleans a lower-surface center region of the substrate.

### TECHNICAL FIELD

The present invention relates to a substrate cleaning device and a substrate cleaning method.

### BACKGROUND ART

A substrate processing apparatus is used to perform various processes on various substrates such as a substrate for an FPD (Flat Panel Display) that is used for a liquid crystal display device, an organic EL (ElectroLuminescence) display device or the like, a semiconductor substrate, a substrate for an optical disc, a substrate for a magnetic disc, a substrate for a magneto-optical disc, a substrate for a photomask, a ceramic substrate or a substrate for a solar cell. A substrate cleaning device is used to clean a substrate.

For example, a substrate cleaning device described in Patent Document 1 includes two suction pads for holding the back-surface peripheral portion of a wafer, a spin chuck for holding the back-surface center portion of the wafer and a brush for cleaning the back surface of the wafer. The two suction pads hold the wafer and move in a transverse direction. In this state, the back-surface center portion of the wafer is cleaned by the brush. Thereafter, the spin chuck receives the wafer from the suction pads. Further, the spin chuck rotates about an axis (rotation shaft) extending in a vertical direction while holding the back-surface center portion of the wafer. In this state, the back-surface peripheral portion of the wafer is cleaned by the brush.
[Patent Document 1]JP 5904169 B2

### SUMMARY OF INVENTION

### Technical Problem

When the peripheral portion of the wafer is held by the suction pads, the center portion of the wafer is displaced downwardly due to its own weight, and the lower surface of the wafer is curved. Further, when the brush is pressed against the back-surface center portion of the wafer from below in order to be brought into contact with the wafer, the center portion of the wafer is displaced upwardly due to a load applied by the brush, and the lower surface of the wafer is curved. In a case in which the upper surface of the brush is flat, the entire upper surface of the brush does not come into contact with the wafer, and the area in which the brush and the wafer come into contact with each other is reduced. Therefore, the frequency of cleaning of the region of the wafer that does not come into contact with the brush is reduced.

An object of the present invention is to provide a substrate cleaning device that can efficiently clean a lower-surface center region of a substrate.

### Solution to Problem

(1) According to one aspect of the present invention, a substrate cleaning device includes a substrate holder that holds an outer peripheral end of a substrate, a cleaner that comes into contact with a lower surface of the substrate to clean the lower surface of the substrate, and a cleaning controller that changes an uplift force for uplifting the cleaner in a period during which the cleaner cleans a lower-surface center region of the substrate. Because the uplift force for uplifting the cleaner in the period during which the cleaner cleans the lower-surface center region of the substrate is changed, the contact surface in which the cleaner and the substrate come into contact with each other varies due to displacement of the substrate. Therefore, it is possible to provide the substrate cleaning device that efficiently clean the lower-surface center region of the substrate.

(2) The cleaning controller continuously changes the uplift force.

(3) The cleaning controller gradually changes the uplift force applied by the cleaner.

(4) The substrate cleaning device further includes a displacement sensor that detects displacement of the substrate, wherein the cleaning controller changes the uplift force such that displacement of the substrate falls within a predetermined range. This can prevent the substrate from being damaged.

(5) According to another aspect of the present invention, a substrate cleaning device includes a substrate holder that holds an outer peripheral end of a substrate, a cleaner that comes into contact with a lower surface of the substrate to clean the lower surface of the substrate, and a controller that changes a force exerted between the cleaner and the substrate in a period during which the cleaner cleans a lower-surface center region of the substrate. Therefore, because the force to be exerted between the cleaner and the substrate in the period during which the cleaner cleans the lower-surface center region of the substrate is changed, the contact surface in which the substrate and the cleaner come into contact with each other can be changed in the period during which the lower-surface center region is cleaned. Therefore, it is possible to provide the substrate cleaning device that efficiently clean the lower-surface center region of the substrate.

(6) The substrate cleaning device further includes a displacement sensor that detects displacement of the substrate, wherein the controller changes a force exerted between the cleaner and the substrate such that displacement of the substrate falls within a predetermined range. This can prevent the substrate from being damaged.

(7) According to yet another aspect of the present invention, a substrate cleaning method is performed in a substrate cleaning device, wherein the substrate cleaning device includes a substrate holder that holds an outer peripheral end of a substrate, and a cleaner that comes into contact with a lower surface of the substrate to clean the lower surface of the substrate, and the substrate cleaning method includes a cleaning control step of changing an uplift force for uplifting the cleaner in a period during which the cleaner cleans a lower-surface center region of the substrate.

(8) According to yet another aspect of the present invention, a substrate cleaning method is performed in a substrate cleaning device, wherein the substrate cleaning device includes a substrate holder that holds an outer peripheral end of a substrate, and a cleaner that comes into contact with a lower surface of the substrate to clean the lower surface of the substrate, and the substrate cleaning method includes a control step of changing a force exerted between the cleaner and the substrate in a period during which the cleaner cleans a lower-surface center region of the substrate.

### Advantageous Effects of Invention

With the present invention, it is possible to efficiently clean the lower-surface center region of the substrate.

### BRIEF DESCRIPTION OF THE DRAWINGS

FIG. 1 is a schematic plan view of a substrate cleaning device according to one embodiment of the present invention.

FIG. 2 is an external perspective view showing the inner configuration of the substrate cleaning device.

FIG. 3 is an external perspective view of a pair of upper holding devices.

FIG. 4 is an external perspective view of upper chucks of FIGS. 1 and 2.

FIG. 5 is a block diagram showing the configuration of a control system of the substrate cleaning device.

FIG. 6 is a schematic diagram for explaining the schematic operation of the substrate cleaning device of FIG. 1.

FIG. 7 is a diagram schematically showing the positional relationship between a substrate and a lower-surface brush with the substrate not displaced.

FIG. 8 is a diagram showing one example of a contact surface in which the substrate and the lower-surface brush come into contact with each other with the substrate not displaced.

FIG. 9 is a diagram schematically showing the positional relationship between the substrate and the lower-surface brush with the substrate displaced to a position lower than a reference position.

FIG. 10 is a diagram showing one example of the contact surface in which the substrate and the lower-surface brush come into contact with each other with the substrate displaced to a position lower than the reference position.

FIG. 11 is a diagram schematically showing the positional relationship between the substrate and the lower-surface brush with the substrate displaced to a position higher than the reference position.

FIG. 12 is a diagram showing one example of the contact surface in which the substrate and the lower-surface brush come into contact with each other with the substrate displaced to a position higher than the reference position.

FIG. 13 is a time chart showing one example of the change of an uplift force.

FIG. 14 is a flowchart showing one example of a flow of an uplift force control process.

FIG. 15 is a time chart showing one example of the change of the uplift force in a first modified example.

FIG. 16 is a flowchart showing one example of a flow of an uplift force control process in the first modified example.

FIG. 17 is an external perspective view showing the inner configuration of a substrate cleaning device 1 in a second embodiment.

FIG. 18 is a flowchart showing one example of a flow of an uplift force control process in the second embodiment.

### DESCRIPTION OF EMBODIMENTS

A substrate cleaning device and a substrate cleaning method according to embodiments of the present invention will be described below with reference to the drawings. In the following description, a substrate refers to a semiconductor substrate, a substrate for an FPD (Flat Panel Display) such as a liquid crystal display device or an organic EL (ElectroLuminescence) display device, a substrate for an optical disc, a substrate for a magnetic disc, a substrate for a magneto-optical disc, a substrate for a photomask, a ceramic substrate, a substrate for a solar battery, or the like. Further, as for a substrate to be used in the present embodiment, at least part of the substrate has a circular outer periphery. For example, the outer periphery except for a notch for positioning is circular.

### First Embodiment

### 1. Configuration of Substrate Cleaning Device

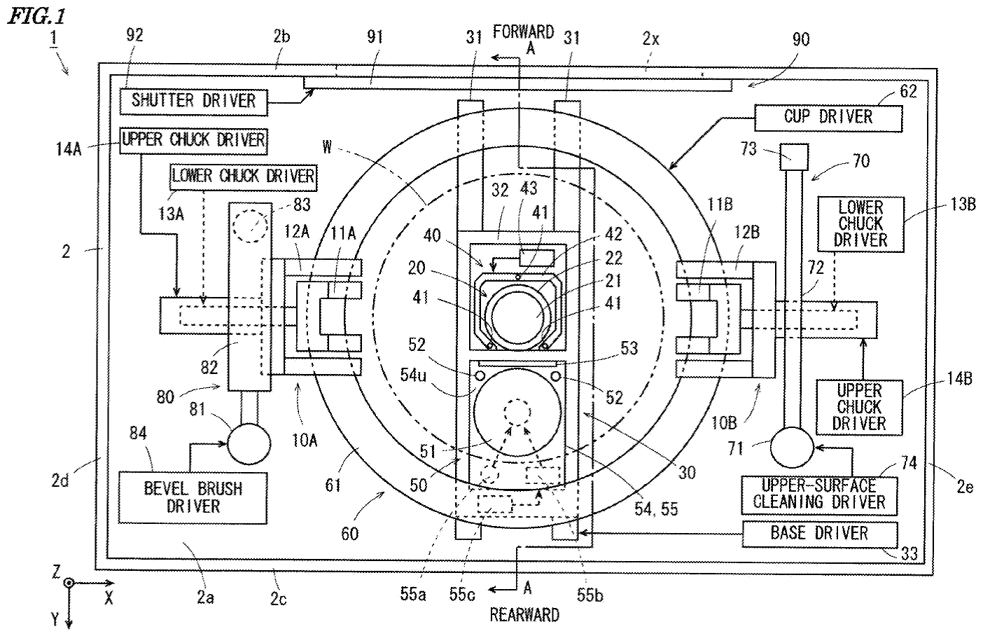

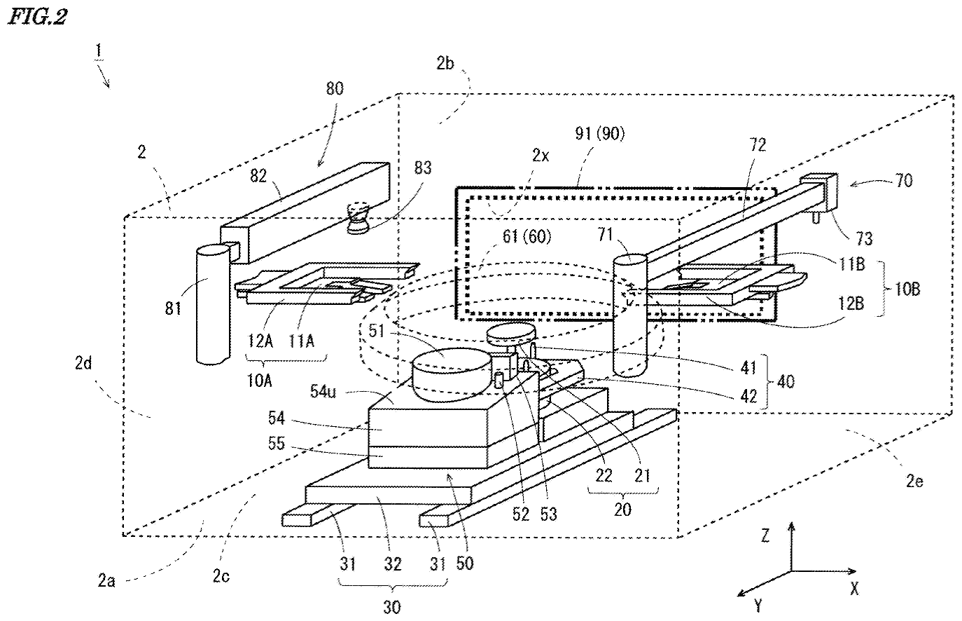

FIG. 1 is a schematic plan view of a substrate cleaning device according to one embodiment of the present invention. FIG. 2 is an external perspective view showing the inner configuration of the substrate cleaning device 1. In the substrate cleaning device 1 according to the present embodiment, X, Y and Z directions orthogonal to one another are defined for the clarity of a positional relationship. In FIG. 1 and the subsequent drawings, the X, Y and Z directions are suitably indicated by arrows. The X and Y directions are orthogonal to each other within a horizontal plane, and the Z direction corresponds to a vertical direction.

As shown in FIG. 1, the substrate cleaning device 1 includes upper holding devices 10A, 10B, a lower holding device 20, a base device 30, a receiving-transferring device 40, a lower-surface cleaning device 50, a cup device 60, an upper-surface cleaning device 70, an end-portion cleaning device 80 and an opening-closing device 90. These constituent elements are provided in a unit casing 2. In FIG. 2, the unit casing 2 is indicated by the dotted lines.

The unit casing 2 has a rectangular bottom surface portion 2a, and four sidewall portions 2b, 2c, 2d, 2e extending upwardly from the four sides of the bottom surface portion 2a. The sidewall portions 2b, 2c are opposite to each other, and the sidewall portions 2d, 2e are opposite to each other. A rectangular opening is formed in the center portion of the sidewall portion 2b. This opening is an inlet-outlet port 2x for a substrate W and is used when the substrate W is carried into and carried out from the unit casing 2. In FIG. 2, the inlet-outlet port 2x is indicated by the thick dotted lines. In the following description, a direction directed outwardly of the unit casing 2 in the Y direction from the inside of the unit casing 2 through the inlet-outlet port 2x (the direction directed from the sidewall portion 2c toward the sidewall portion 2b) is referred to as forward, and its opposite direction (the direction directed from the sidewall portion 2b toward the sidewall portion 2c) is referred to as rearward.

The opening-closing device 90 is provided in a portion in which the inlet-outlet port 2x is formed and its vicinal region in the sidewall portion 2b. The opening-closing device 90 includes a shutter 91 that is configured to be capable of opening and closing the inlet-outlet port 2x and a shutter driver 92 that drives the shutter 91. In FIG. 2, the shutter 91 is indicated by the thick two-dots and dash lines. The shutter driver 92 drives the shutter 91 to open the inlet-outlet port 2x when the substrate W is carried into and carried out from the substrate cleaning device 1. Further, the shutter driver 92 drives the shutter 91 to close the inlet-outlet port 2x when the substrate W is cleaned in the substrate cleaning device 1.

The base device 30 is provided in the center portion of the bottom surface portion 2a. The base device 30 includes linear guides 31, a mobile base 32 and a base driver 33. The linear guides 31 include two rails and are provided to extend in the Y direction from the positions in the vicinity of the sidewall portion 2b to the positions in the vicinity of the sidewall portion 2c in plan view. The mobile base 32 is provided to be movable in the Y direction on the two rails of the linear guides 31. The base driver 33 includes a pulse motor, for example, and moves the mobile base 32 in the Y direction on the linear guides 31.

The lower holding device 20 and the lower-surface cleaning device 50 are provided on the mobile base 32 to be arranged in the Y direction. The lower holding device 20 includes a suction holder 21 and a suction holding driver 22. The suction holder 21 is a so-called spin chuck, has a circular suction surface that can hold a lower surface of the substrate W by suction and is configured to be rotatable about an axis extending in an upward-and-downward direction (the axis extending in the Z direction). In the following description, a region that is to be sucked by the suction surface of the suction holder 21 in the lower surface of the substrate W when the substrate W is held by suction by the suction holder 21 is referred to as a lower-surface center region. On the other hand, a region, surrounding the lower-surface center region, in the lower surface of the substrate W is referred to as a lower-surface outer region.

The suction holding driver 22 includes a motor. The motor of the suction holding driver 22 is provided on the mobile base 32 such that its rotation shaft projects upwardly. The suction holder 21 is attached to upper end portion of the rotation shaft of the suction holding driver 22. Further, a suction path is formed in the rotation shaft of the suction holding driver 22 to hold the substrate W by suction with use of the suction holder 21. The suction path is connected to a suction device (not shown). The suction holding driver 22 rotates the suction holder 21 about the above-mentioned rotation shaft.

On the mobile base 32, the receiving-transferring device 40 is further provided in the vicinity of the lower holding device 20. The receiving-transferring device 40 includes a plurality (three in the present example) of support pins 41, a pin coupling member 42 and a pin lifting-lowering driver 43. The pin coupling member 42 is formed to surround the suction holder 21 in plan view and couples the plurality of support pins 41 to one another. The plurality of support pins 41 extend upwardly by a certain length from the pin coupling member 42 while being coupled to one another by the pin coupling member 42. The pin lifting-lowering driver 43 lifts and lowers the pin coupling member 42 on the mobile base 32. Thus, the plurality of support pins 41 are lifted and lowered relative to the suction holder 21.

The lower-surface cleaning device 50 includes a lower-surface brush 51, two liquid nozzles 52, a gas injector 53, a lifting-lowering supporter 54, a movement supporter 55, a lower-surface brush operation driver 55a, a lower-surface brush lifting-lowering driver 55b and a lower-surface brush movement driver 55c. The movement supporter 55 is provided to be movable in the Y direction with respect to the lower holding device 20 in a certain region on the mobile base 32. As shown in FIG. 2, the lifting-lowering supporter 54 is provided on the movement supporter 55 to be liftable and lowerable. The lifting-lowering supporter 54 has an upper surface 54u that is inclined downwardly in a direction away from the suction holder 21 (rearwardly in the present example).

As shown in FIG. 1, the lower-surface brush 51 has a circular outer shape in plan view and is formed to be relatively large in the present embodiment. Specifically, the diameter of the lower-surface brush 51 is larger than the diameter of the suction surface of the suction holder 21 and is 1.3 times of the diameter of the suction surface of the suction holder 21, for example. Further, the diameter of the lower-surface brush 51 is larger than ⅓ of the diameter of the substrate W and smaller than ½ of the diameter of the substrate W. The diameter of the substrate W is 300 mm, for example.

The lower-surface brush 51 has a cleaning surface that can come into contact with the lower surface of the substrate W. Further, the lower-surface brush 51 is attached to the upper surface 54u of the lifting-lowering supporter 54 such that the cleaning surface is directed upwardly and the cleaning surface is rotatable about an axis extending in the upward-and-downward direction through the center of the cleaning surface.

Each of the two liquid nozzles 52 is attached to the upper surface 54u of the lifting-lowering supporter 54 to be located in the vicinity of the lower-surface brush 51. Further, each of the two liquid nozzles 52 is attached to the upper surface 54u such that a liquid discharge port is directed upwardly. A lower-surface cleaning liquid supplier 56 (FIG. 5) is connected to the liquid nozzles 52. The lower-surface cleaning liquid supplier 56 supplies a cleaning liquid to the liquid nozzles 52. When the substrate W is cleaned by the lower-surface brush 51, the liquid nozzles 52 discharge the cleaning liquid supplied from the lower-surface cleaning liquid supplier 56 to the lower surface of the substrate W. In the present embodiment, pure water is used as the cleaning liquid to be supplied to the liquid nozzles 52.

The gas injector 53 is a slit-like gas injection nozzle having a gas injection port extending in one direction. The gas injector 53 is attached to the upper surface 54u of the lifting-lowering supporter 54 to be located between the lower-surface brush 51 and the suction holder 21 in plan view. Further, the gas injector 53 is attached to the upper surface 54u of the lifting-lowering supporter 54 such that a gas injection port is directed upwardly. An injection gas supplier 57 (FIG. 5) is connected to the gas injector 53. The injection gas supplier 57 supplies gas to the gas injector 53. In the present embodiment, an inert gas such as a nitrogen gas is used as the gas to be supplied to the gas injector 53. The gas injector 53 injects the gas supplied from the injection gas supplier 57 to the lower surface of the substrate W during cleaning of the substrate W by the lower-surface brush 51 and during drying of the lower surface of the substrate W, as described below. In this case, a strip-shaped gas curtain extending in the X direction is formed between the lower-surface brush 51 and the suction holder 21.

The lower-surface brush operation driver 55a includes an air cylinder and an electropneumatic regulator that drives the air cylinder. When the substrate W is cleaned by the lower-surface brush 51, the lower-surface brush operation driver 55a controls the electropneumatic regulator to drive the air cylinder and controls an uplift force with which the lower-surface brush 51 is pressed against the lower surface of the substrate W.

Further, the lower-surface brush operation driver 55a further includes a motor, and drives the motor with the lower-surface brush 51 being in contact with the lower surface of the substrate W when the substrate W is cleaned by the lower-surface brush 51. Thus, the lower-surface brush 51 is rotated. Details of the lower-surface brush operation driver 55a will be described below.

The lower-surface brush lifting-lowering driver 55b includes a stepping motor or an air cylinder, and lifts and lowers the lifting-lowering supporter 54 with respect to the movement supporter 55. The lower-surface brush movement driver 55c includes a motor, and moves the movement supporter 55 in the Y direction on the mobile base 32. Here, the position of the lower holding device 20 in the mobile base 32 is fixed. Therefore, when being moved by the lower-surface brush movement driver 55c in the Y direction, the movement supporter 55 is moved relative to the lower holding device 20. In the following description, the position of the lower-surface cleaning device 50 being located closest to the lower holding device 20 on the mobile base 32 is referred to as a proximal position, and the position of the lower-surface cleaning device 50 located farthest from the lower holding device 20 on the mobile base 32 is referred to as a distal position.

The cup device 60 is further provided in the center portion of the bottom surface portion 2a. The cup device 60 includes a cup 61 and a cup driver 62. The cup 61 is provided to surround the lower holding device 20 and the base device 30 in plan view, and be liftable and lowerable. In FIG. 2, the cup 61 is indicated by the dotted lines. The cup driver 62 moves the cup 61 between a lower cup position and an upper cup position in accordance with which portion of the lower surface of the substrate W is to be cleaned by the lower-surface brush 51. The lower cup position is a height position at which the upper end portion of the cup 61 is located farther downwardly than the substrate W held by suction by the suction holder 21. Further, the upper cup position is a height position at which the upper end portion of the cup 61 is located farther upwardly than the suction holder 21.

At height positions farther upward than the cup 61, the pair of upper holding devices 10A, 10B are provided to be opposite to each other with the base device 30 held therebetween in plan view. The upper holding device 10A includes a lower chuck 11A, an upper chuck 12A, a lower chuck driver 13A and an upper chuck driver 14A. The upper holding device 10B includes a lower chuck 11B, an upper chuck 12B, a lower chuck driver 13B and an upper chuck driver 14B. The upper holding devices 10A, 10B form a substrate alignment device of the present invention.

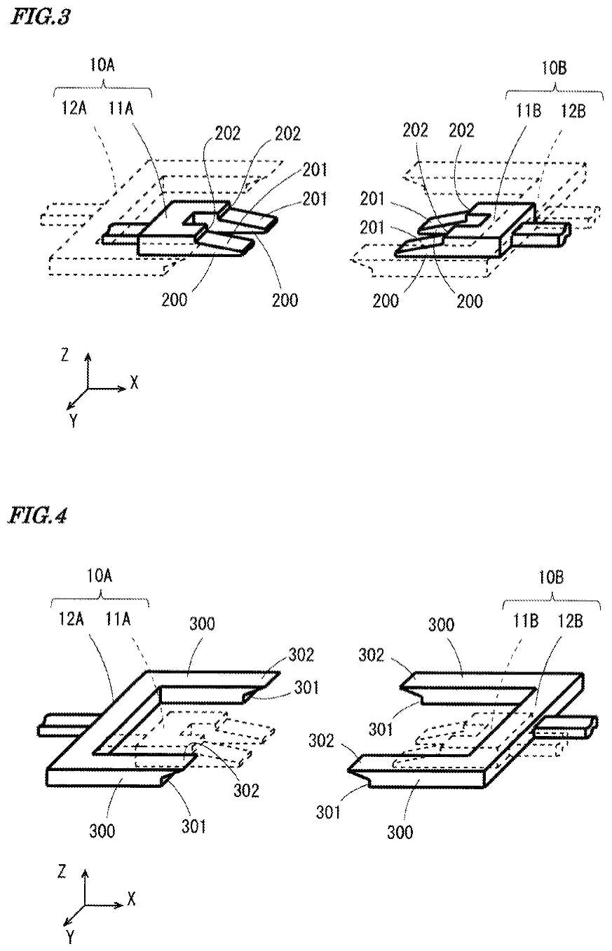

FIG. 3 is an external perspective view of the pair of upper holding devices. In FIG. 3, the lower chucks 11A, 11B are indicated by the thick solid lines. Further, the upper chucks 12A, 12B are indicated by the dotted lines. In regard to the external perspective view of FIG. 3, the expansion and contraction rates of each component are different from those in the outer perspective view of FIG. 2 in order to facilitate understanding of the shapes of the lower chucks 11A, 11B.

As shown in FIG. 3, the lower chucks 11A, 11B are arranged symmetrically with respect to a vertical plane extending in the Y direction (a forward-and-rearward direction) through the center of the suction holder 21 in plan view, and are provided to be movable in the X direction in a common horizontal plane. Each of the lower chucks 11A, 11B has two support pieces 200. Each support piece 200 is provided with an inclined support surface 201 and a movement limiting surface 202.

In the lower chuck 11A, the inclined support surface 201 of each support piece 200 is formed so as to be capable of supporting the outer peripheral end of the substrate W from below and extend obliquely downwardly toward the lower chuck 11B. The movement limiting surface 202 extends upwardly by a certain distance from the upper end portion of the inclined support surface 201 to generate a level difference at the upper end portion of the lower chuck 11A. On the other hand, in the lower chuck 11B, the inclined support surface 201 of each support piece 200 is formed so as to be capable of supporting the outer peripheral end of the substrate W from below and extend obliquely downwardly toward the lower chuck 11A. The movement limiting surface 202 extends upwardly from the upper end portion of the inclined support surface 201 to generate a level difference at the upper end portion of the lower chuck 11B.

The lower chuck drivers 13A, 13B include air cylinders or motors as actuators. The lower chuck drivers 13A, 13B move the lower chucks 11A, 11B such that the lower chucks 11A, 11B are closer to each other or are farther away from each other. Here, in a case in which the target positions of the lower chucks 11A, 11B in the X direction are predetermined, the lower chuck drivers 13A, 13B can respectively adjust the positions of the lower chucks 11A, 11B in the X direction based on the information about the target positions. For example, it is possible to place the substrate W on the plurality of inclined support surfaces 201 of the lower chucks 11A, 11B by making the distance between the lower chucks 11A, 11B be smaller than the outer diameter of the substrate W. In this case, the outer peripheral end of the substrate W is supported by each inclined support surface 201.

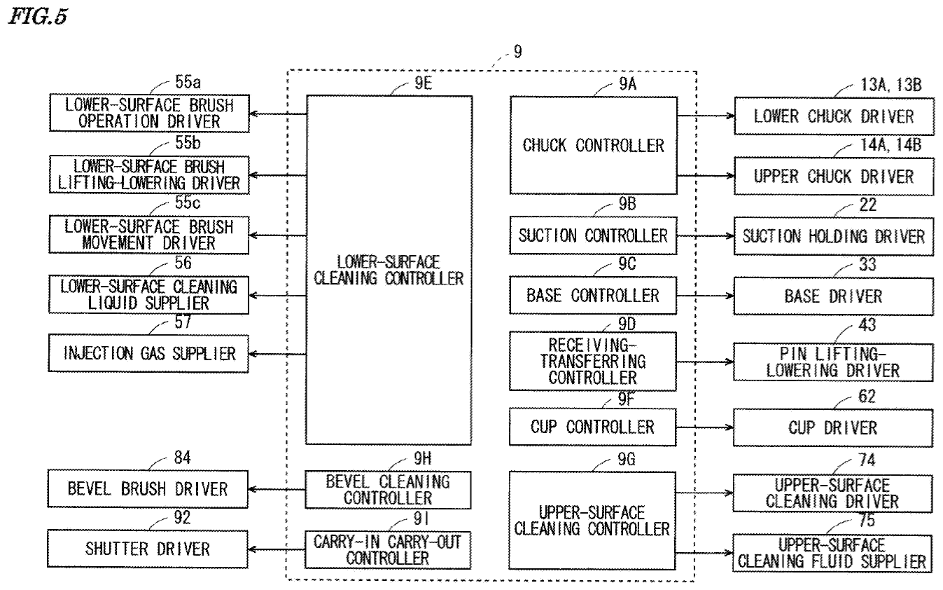

FIG. 4 is an external perspective view of the upper chucks 12A, 12B of FIGS. 1 and 2. In FIG. 4, the upper chucks 12A, 12B are indicated by the thick solid lines. Further, the lower chucks 11A, 11B are indicated by the dotted lines. In regard to the external perspective view of FIG. 4, the expansion and contraction rates of each component are different from those in the external perspective view of FIG. 2 in order to facilitate understanding of the shapes of the upper chucks 12A, 12B.

As shown in FIG. 4, similarly to the lower chucks 11A, 11B, the upper chucks 12A, 12B are arranged symmetrically with respect to the vertical plane extending in the Y direction (the forward-and-rearward direction) through the center of the suction holder 21 in plan view, and are provided to be movable in the X direction in a common horizontal plane. Each of the upper chucks 12A, 12B has two holding pieces 300. Each holding piece 300 has an abutment surface 301 and a projection 302.

In the upper chuck 12A, the abutment surface 301 of each holding piece 300 is formed so as to face the upper chuck 12B at the lower portion of the tip of the holding piece 300, and is orthogonal to the X direction. The projection 302 is formed so as to project from the upper end of the abutment surface 301 toward the upper chuck 12B by a predetermined distance. On the other hand, in the upper chuck 12B, the abutment surface 301 of each holding piece 300 is formed so as to face the upper chuck 12A at the lower portion of the tip of the holding piece 300, and is orthogonal to the X direction. The projection 302 is formed so as to project from the upper end of the abutment surface 301 toward the upper chuck 12A by a predetermined distance.

The upper chuck drivers 14A, 14B include air cylinders or motors as actuators. The upper chuck drivers 14A, 14B move the upper chucks 12A, 12B such that the upper chucks 12A, 12B are closer to each other or farther away from each other. Here, in a case in which the target positions of the upper chucks 12A, 12B in the X direction are predetermined, the upper chuck drivers 14A, 14B can respectively adjust the positions of the upper chucks 12A, 12B in the X direction based on the information about the target positions.

In the above-mentioned upper holding devices 10A, 10B, the upper chucks 12A, 12B are moved toward the outer peripheral end of the substrate W supported by the lower chucks 11A, 11B. The two abutment surfaces 301 of the upper chuck 12A and the two abutment surfaces 301 of the upper chuck 12B come into contact with a plurality of portions of the outer peripheral end of the substrate W, whereby the outer peripheral end of the substrate W is held and the substrate W is firmly fixed.

In the present embodiment, the upper chuck driver 14B adjusts the distance between the upper chuck 12A and the upper chuck 12B such that the pressing forces with which the two abutment surfaces 301 of the upper chuck 12A and the two abutment surfaces 301 of the upper chuck 12B press the substrate W are constant. A force sensor is provided at one of the two abutment surfaces 301 of the upper chuck 12A and the two abutment surfaces 301 of the upper chuck 12B. The upper chuck driver 14B adjusts the distance between the upper chuck 12A and the upper chuck 12B such that an output value of the sensor is a predetermined target values. Therefore, the pressing forces with which the pair of upper holding devices 10A, 10B hold the substrate W are constant.

As shown in FIG. 1, at a position near one side of the cup 61, the upper-surface cleaning device 70 is provided to be located in the vicinity of the upper holding device 10B in plan view. The upper-surface cleaning device 70 includes a rotation support shaft 71, an arm 72, a spray nozzle 73 and an upper-surface cleaning driver 74.

The rotation support shaft 71 is supported on the bottom surface portion 2a by the upper-surface cleaning driver 74 to extend in the upward-and-downward direction, and to be liftable, lowerable and rotatable. As shown in FIG. 2, at a position farther upward than the upper holding device 10B, the arm 72 is provided to extend in the horizontal direction from the upper end portion of the rotation support shaft 71. The spray nozzle 73 is attached to the tip portion of the arm 72.

An upper-surface cleaning fluid supplier 75 (FIG. 5) is connected to the spray nozzle 73. The upper-surface cleaning fluid supplier 75 supplies a cleaning liquid and gas to the spray nozzle 73. In the present embodiment, pure water is used as the cleaning liquid to be supplied to the spray nozzle 73, and an inert gas such as a nitrogen gas is used as the gas to be supplied to the spray nozzle 73. When the upper surface of the substrate W is cleaned, the spray nozzle 73 mixes the cleaning liquid and the gas supplied from the upper-surface cleaning fluid supplier 75 to produce a fluid mixture, and injects the produced fluid mixture downwardly.

The upper-surface cleaning driver 74 includes one or a plurality of pulse motors, an air cylinder and the like, lifts and lowers the rotation support shaft 71, and rotates the rotation support shaft 71. With the above-mentioned configuration, on the upper surface of the substrate W held by suction and rotated by the suction holder 21, the spray nozzle 73 is moved in a circular arc shape. Thus, the entire upper surface of the substrate W can be cleaned.

As shown in FIG. 1, at a position near the other side of the cup 61, the end-portion cleaning device 80 is provided to be located in the vicinity of the upper holding device 10A in plan view. The end-portion cleaning device 80 includes a rotation support shaft 81, an arm 82, a bevel brush 83 and a bevel brush driver 84.

The rotation support shaft 81 is supported on the bottom surface portion 2a by the bevel brush driver 84 to extend in the upward-and-downward direction and to be liftable, lowerable and rotatable. As shown in FIG. 2, at a position farther upward than the upper holding device 10A, the arm 82 is provided to extend in the horizontal direction from the upper end portion of the rotation support shaft 81. At the tip portion of the arm 82, the bevel brush 83 is provided to project downwardly and to be rotatable about an axis extending in the upward-and-downward direction.

In the bevel brush 83, its upper half portion has an inverse trapezoidal shape, and its lower half portion has a trapezoidal shape. With this bevel brush 83, the outer peripheral end of the substrate W can be cleaned by the center portion in the upward-and-downward direction of the outer peripheral surface.

The bevel brush driver 84 includes one or a plurality of pulse motors, an air cylinder and the like, lifts and lowers the rotation support shaft 81 and rotates the rotation support shaft 81. With the above-mentioned configuration, the center portion of the outer peripheral surface of the bevel brush 83 is brought into contact with the outer peripheral end of the substrate W held by suction and rotated by the suction holder 21. Thus, the entire outer peripheral end of the substrate W can be cleaned.

Here, the bevel brush driver 84 further includes a motor built in the arm 82. The motor rotates the bevel brush 83 provided at the tip portion of the arm 82 about the axis extending in the upward-and-downward direction. Therefore, when the outer peripheral end of the substrate W is cleaned, a cleaning force of the bevel brush 83 in the outer peripheral end of the substrate W is improved by rotation of the bevel brush 83.

FIG. 5 is a block diagram showing the configuration of a control system of the substrate cleaning device 1. The control device 9 of FIG. 5 includes a CPU (Center Processing Unit), a RAM (Random Access Memory), a ROM (Read Only Memory) and a storage device. The RAM is used as a work region for the CPU. The ROM stores a system program. The storage device stores a control program.

As shown in FIG. 5, the control device 9 includes a chuck controller 9A, a suction controller 9B, a base controller 9C, a receiving-transferring controller 9D, a lower-surface cleaning controller 9E, a cup controller 9F, an upper-surface cleaning controller 9G, a bevel cleaning controller 9H and a carry-in carry-out controller 9I as functions. The functions of the control device 9 are implemented by execution of a substrate cleaning program stored in the storage device on the RAM by the CPU. Part or all of the functions of the control device 9 may be implemented by hardware such as an electronic circuit.

The chuck controller 9A controls the lower chuck drivers 13A, 13B and the upper chuck drivers 14A, 14B in order to receive the substrate W that is carried into the substrate cleaning device 1 and hold the substrate W at a position above the suction holder 21. The suction controller 9B controls the suction holding driver 22 in order to hold the substrate W by suction using the suction holder 21 and rotate the substrate W held by suction.

The base controller 9C controls the base driver 33 in order to move the mobile base 32 with respect to the substrate W held by the upper holding devices 10A, 10B. The receiving-transferring controller 9D controls the pin lifting-lowering driver 43 in order to move the substrate W between a height position of the substrate W held by the upper holding devices 10A, 10B and a height position of the substrate W held by the suction holder 21.

The lower-surface cleaning controller 9E controls the lower-surface brush operation driver 55a, the lower-surface brush lifting-lowering driver 55b, the lower-surface brush movement driver 55c, the lower-surface cleaning liquid supplier 56 and the injection gas supplier 57 in order to clean the lower surface of the substrate W. The cup controller 9F controls the cup driver 62 in order for the cup 61 to receive the cleaning liquid splashed from the substrate W when the substrate W held by suction by the suction holder 21 is cleaned.

The upper-surface cleaning controller 9G controls the upper-surface cleaning driver 74 and the upper-surface cleaning fluid supplier 75 in order to clean the upper surface of the substrate W held by suction by the suction holder 21. The bevel cleaning controller 9H controls the bevel brush driver 84 for cleaning of the outer peripheral end of the substrate W held by suction by the suction holder 21. The carry-in carry-out controller 9I controls the shutter driver 92 in order to open and close the inlet-outlet port 2x of the unit casing 2 when the substrate W is carried into and carried out from the substrate cleaning device 1.

### 2. Schematic Operation of Substrate Cleaning Device During Cleaning for Lower-Surface Center Region

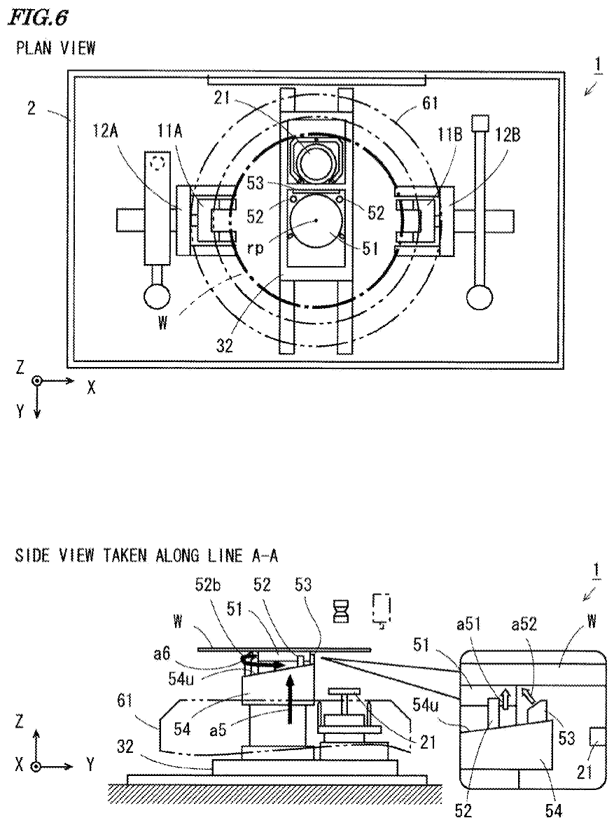

FIG. 6 is a schematic diagram for explaining the schematic operation of the substrate cleaning device 1. In FIG. 6, a plan view of the substrate cleaning device 1 is shown in the upper field. Further, the side view of the lower holding device 20 and its peripheral portions as viewed in the Y direction is shown in the bottom field. The side view in the bottom field corresponds to the side view of the substrate cleaning device 1 taken along the line A-A of FIG. 1. The expansion and contraction rates of part of the constituent elements are different for the plan view in the upper field and the side view in the bottom field in order to facilitate understanding of the shape and operation state of each constituent element in the substrate cleaning device 1. Further, the cup 61 is indicated by the two-dots and dash lines, and the outer shape of the substrate W is indicated by the thick one-dot and dash lines.

With reference to FIG. 6, as indicated by the thick solid arrow a5, the lifting-lowering supporter 54 is lifted such that the cleaning surface of the lower-surface brush 51 comes into contact with the lower-surface center region of the substrate W. Further, as indicated by the thick solid arrow a6, the lower-surface brush 51 is rotated (spins) about the axis extending in the upward-and-downward direction. Thus, contaminants adhering to the lower-surface center region of the substrate W are physically stripped by the lower-surface brush 51.

In the bottom field in FIG. 6, the enlarged side view of a portion in which the lower-surface brush 51 comes into contact with the lower surface of the substrate W is shown in a balloon. As shown in the balloon, with the lower-surface brush 51 in contact with the substrate W, the liquid nozzle 52 and the gas injector 53 are held at positions close to the lower surface of the substrate W. At this time, as indicated by the outlined arrow a51, the liquid nozzle 52 discharges the cleaning liquid toward the lower surface of the substrate W at a position in the vicinity of the lower-surface brush 51. Thus, the cleaning liquid that has been supplied to the lower surface of the substrate W from the liquid nozzle 52 is guided to the contact portion in which the lower-surface brush 51 and the substrate W come into contact with each other, whereby contaminants that have been removed from the back surface of the substrate W by the lower-surface brush 51 are washed away by the cleaning liquid. In this manner, in the lower-surface cleaning device 50, the liquid nozzle 52 is attached to the lifting-lowering supporter 54 together with the lower-surface brush 51. Thus, the cleaning liquid can be supplied efficiently to a portion to be cleaned in the lower surface of the substrate W by the lower-surface brush 51. Therefore, the consumption of the cleaning liquid is reduced, and excessive splashing of the cleaning liquid is suppressed.

Next, in the state shown in FIG. 6, when the cleaning of the lower-surface center region of the substrate W is completed, the rotation of the lower-surface brush 51 is stopped, and the lifting-lowering supporter 54 is lowered such that the cleaning surface of the lower-surface brush 51 is spaced apart from the substrate W by a predetermined distance.

Further, discharging of the cleaning liquid from the liquid nozzle 52 to the substrate W is stopped. At this time, the injection of gas from the gas injector 53 to the substrate W continues.

### 3. Uplift Force Control for Lower-surface Brush

In a period during which the lower-surface brush 51 cleans the lower-surface center region of the substrate W, the lower-surface brush operation driver 55a varies a force for uplifting the lower-surface brush 51 and pressing the lower-surface brush 51 against the lower surface of the substrate W. Hereinafter, a force for uplifting the lower-surface brush 51 is referred to as an uplift force.

In the present embodiment, the pair of upper holding devices 10A, 10B that are arranged to be opposite to each other with the substrate W provided therebetween in plan view hold the substrate W, so that the substrate W is firmly fixed. Because the substrate W has a predetermined weight, the substrate W is curved due to gravity. In this case, downward displacement of the center portion of the substrate W is maximized. Further, the pressing forces with which the pair of upper holding devices 10A, 10B hold the substrate W are applied to the substrate W. Therefore, the amount of downward displacement of the center portion of the substrate W is defined by the resultant force of the gravity applied to the substrate W and the pressing forces received by the substrate W from the upper holding devices 10A, 10B. Due to the pressing forces received by the substrate W from the upper holding devices 10A, 10B, with the substrate W deformed to have a downwardly protruding shape, a downward force is exerted on the center portion of the substrate W. On the other hand, due to the pressing forces received by the substrate W from the upper holding devices 10A, 10B, with the substrate W deformed to have an upwardly protruding shape, an upward force is exerted on the center portion of the substrate W. In the present embodiment, the pressing forces, which the substrate W receives from the upper holding devices 10A, 10B, are constant.

On the other hand, in a period during which the lower-surface brush 51 cleans the lower-surface center region of the substrate W, the lower-surface brush 51 is pressed against the lower surface of the substrate W. At this time, whether the center portion of the substrate W is displaced is defined by the resultant force of the gravity applied to the substrate W and the pressing forces applied to the substrate W by the upper holding devices 10A, 10B, and the uplift force applied to the lower-surface brush 51. The lower-surface brush operation driver 55a varies the uplift force, so that the displacement of the center portion of the substrate W is adjusted. Here, with the position at which the substrate W is held by the pair of upper holding devices 10A, 10B as a reference position, an amount of displacement of the substrate W is indicated by the distance in the vertical direction between the position of the center portion of the substrate W and the reference position. The value of an amount of displacement is negative when the center portion of substrate W is located at a position lower than the reference position, and is positive when the center portion of the substrate W is located at a position higher than the reference position. Further, the value of the maximum amount of displacement that allows the center portion of the substrate W to be displaced to a position higher than the reference position is referred to as an upper limit value, and the value of the minimum amount of displacement that allows the center portion of the substrate W to be displaced to a position lower than the reference position is referred to as a lower limit value.

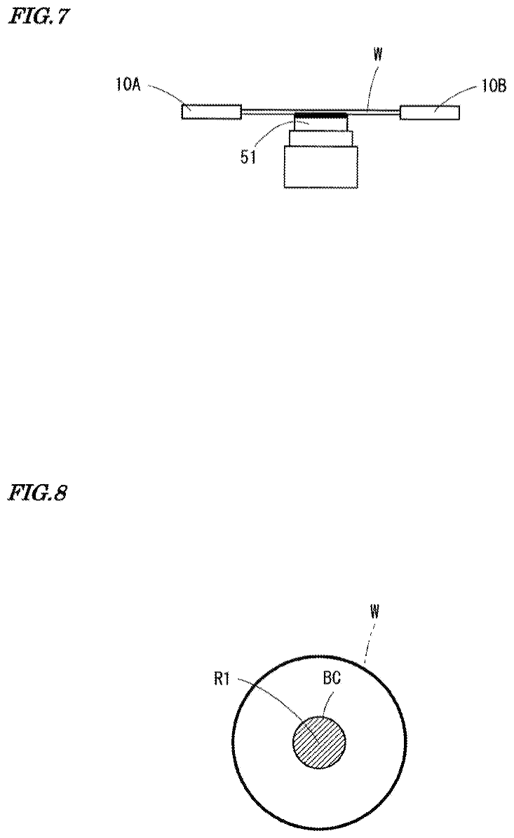

FIG. 7 is a diagram schematically showing the positional relationship between the substrate and the lower-surface brush with the substrate not being displaced. FIG. 8 is a diagram showing one example of a contact surface of the substrate that comes into contact with the lower-surface brush with the substrate not being displaced. In FIG. 7, the region in which the substrate W and the lower-surface brush 51 are in contact with each other is indicated by the thick line. In FIG. 8, the region in which the substrate W and the lower-surface brush 51 are in contact with each other is indicated by hatching.

With reference to FIGS. 7 and 8, the center portion of the substrate W is located at the reference position. In this case, the amount of displacement of the substrate W is zero, the entire substrate W is substantially horizontal, and a lower-surface center region BC of the substrate W is flat. On the other hand, the upper surface of the lower-surface brush 51 is substantially horizontal. Therefore, the lower-surface brush 51 and the substrate W are in contact with each other in an entire region R1 equivalent to the entire lower-surface center region BC. In this case, the force exerted between the lower-surface brush 51 and the lower-surface center region BC is evenly distributed to the entire region R1.

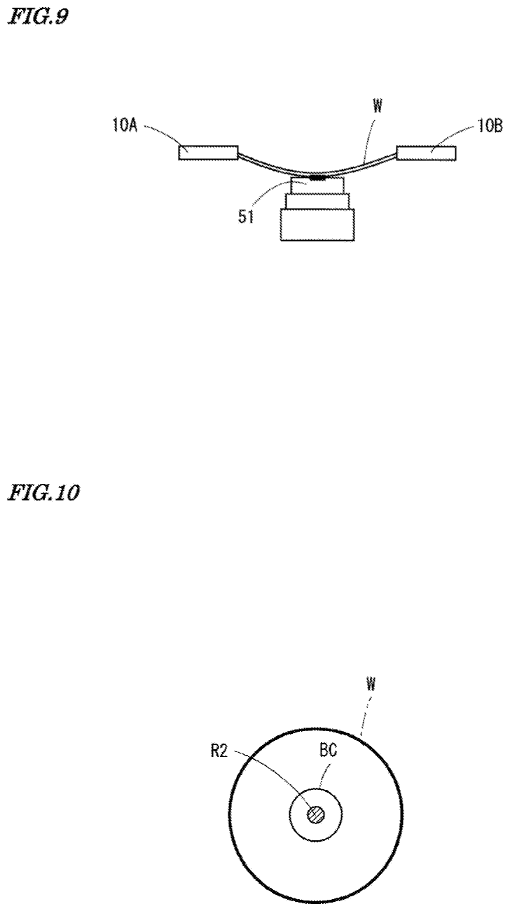

FIG. 9 is a diagram schematically showing the positional relationship between the substrate and the lower-surface brush when the value of the amount of displacement of the substrate is negative. FIG. 10 is a diagram showing one example of the contact surface of the substrate that comes into contact with the lower-surface brush when the value of the amount of displacement of the substrate is negative. In FIG. 9, the region in which the substrate W and the lower-surface brush 51 are in contact with each other is indicated by the thick line. In FIG. 10, the region in which the substrate W and the lower-surface brush 51 are in contact with each other is indicated by hatching.

With reference to FIG. 9, in a case in which the center of the substrate W is displaced to a position lower than the reference position and the value of the amount of displacement is negative, the substrate W has a downwardly protruding shape, and the lower-surface center region BC has a curved surface. On the other hand, the upper surface of the lower-surface brush 51 is substantially horizontal. Therefore, the entire upper surface of the lower-surface brush 51 does not come into contact with the substrate W. With reference to FIG. 10, the lower-surface brush 51 and the substrate W come into contact with each other in a circular or oval center region R2 in the lower-surface center region BC, and the center region R2 includes the center portion of the substrate W and has a diameter smaller than that of the lower-surface center region BC.

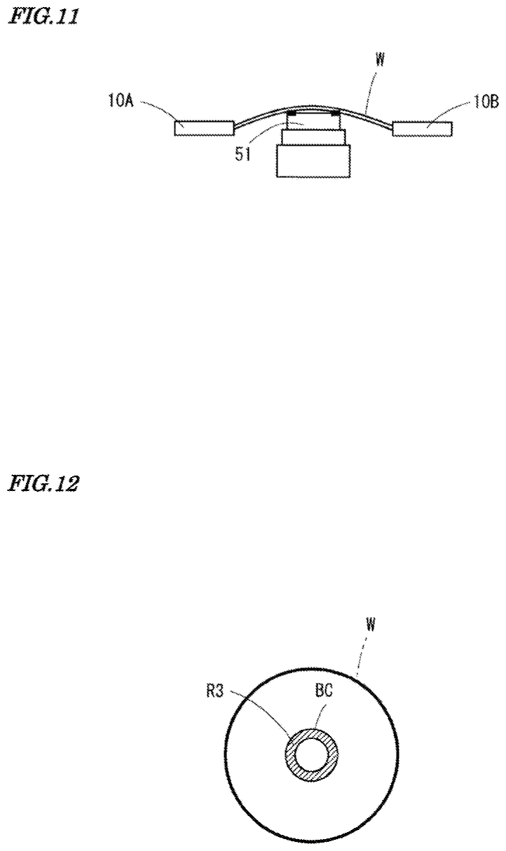

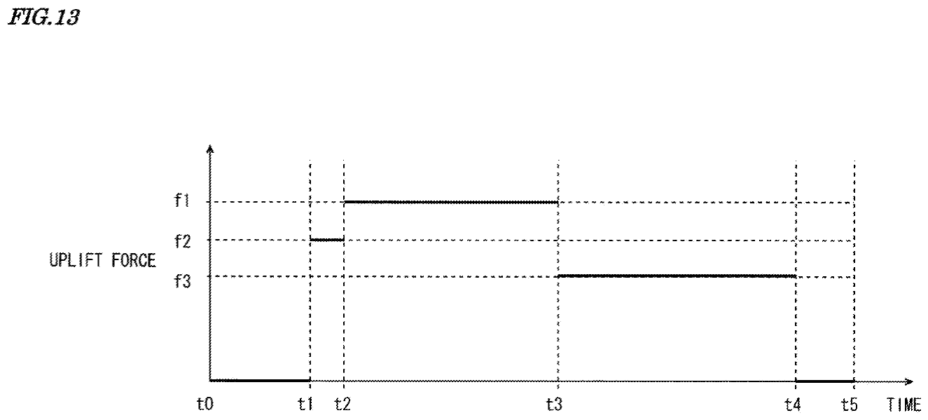

FIG. 11 is a diagram schematically showing the positional relationship between the substrate and the lower-surface brush when the value of the amount of displacement of the substrate is positive. FIG. 12 is a diagram showing one example of the contact surface of the substrate that comes into contact with the lower-surface brush when the value of the amount of displacement of the substrate is positive. In FIG. 11, the region in which the substrate W and the lower-surface brush 51 are in contact with each other is indicated by the thick lines. In FIG. 12, the region in which the substrate W and the lower-surface brush 51 are in contact with each other is indicated by hatching.

With reference to FIG. 11, in a case in which the center of the substrate W is displaced and the value of the amount of displacement is positive, the lower-surface center region has an upwardly protruding shape, and the lower-surface center region BC has a curved surface. On the other hand, the upper surface of the lower-surface brush 51 is substantially horizontal. Therefore, the entire upper surface of the lower-surface brush 51 does not come into contact with the substrate W. With reference to FIG. 12, the lower-surface brush 51 and the substrate W come into contact with each other in an annular region R3 in the lower-surface center region BC, and the annular region R3 includes the outer periphery and excludes the center portion of the substrate W.

FIG. 13 is a time chart showing one example of the change of the uplift force. In the time chart of FIG. 13, the ordinate indicates the uplift force, and the abscissa indicates time. With reference to FIG. 13, at a point t0 in time before the cleaning of the lower-surface center region BC of the substrate W by the lower-surface brush 51 is started, the lower-surface brush operation driver 55a does not apply a force to the lower-surface brush 51. At a point t1 in time before the cleaning of the lower-surface center region BC of the substrate W by the lower-surface brush 51 is started, the lower-surface brush operation driver 55a controls the electropneumatic regulator to apply an uplift force f2 to the lower-surface brush 51. The uplift force f2 is defined by the resultant force of the gravity of the substrate W and the pressing forces with which the pair of upper holding devices 10A, 10B hold the substrate W. Specifically, the uplift force f2 has a predetermined value, which can cause the center portion of the substrate W to be kept displaced and can cause the value of the amount of displacement of the substrate W to be kept negative and to be kept being the lower limit value. Therefore, at the point t1 in time, the value of the amount of displacement of the center portion of the substrate W is negative as shown in FIGS. 9 and 10.

Then, at a point t2 in time, the lower-surface brush operation driver 55a controls the electropneumatic regulator to apply an uplift force f1 to the lower-surface brush 51. The uplift force f1 has a value larger than that of the uplift force f2. With the center portion of the substrate W being displaced and being located at a position lower than the reference position, the pressing forces with which the pair of upper holding devices 10A, 10B hold the substrate W are exerted in such a direction that the center portion of the substrate W is moved to a lower position. Because the uplift force f1 is larger than the uplift force f2, the lower-surface brush 51 is lifted, and the center portion of the substrate W is uplifted, after the point t2 in time.

A point t3 in time is a point in time at which half of a cleaning period that is predetermined as a period during which the lower-surface brush 51 cleans the lower-surface center region BC of the substrate W elapses. The uplift force f1 is defined such that, with the uplift force f1 applied, the center of the substrate W is located at the reference position in the period from the point t2 to the point t3 in time.

At the point t3 in time at which the center of the substrate W is located at the reference position, the lower-surface brush operation driver 55a controls the electropneumatic regulator to apply an uplift force t3 to the lower-surface brush 51. With the center portion of the substrate W being displaced and being located at a position higher than the reference position, the pressing forces with which the pair of upper holding devices 10A, 10B hold the substrate W are exerted in such a direction that the center portion of the substrate W is moved to a higher position. Therefore, although the uplift force f3 has a value smaller than that of the uplift force f2, the lower-surface brush 51 is lifted, and the center portion of the substrate W is uplifted, after the point t3 in time.

A point t4 in time is a point in time at which the cleaning period that is predetermined as the period during which the lower-surface brush 51 cleans the lower-surface center region BC of the substrate W elapses. The uplift force f3 is defined such that, with the uplift force f3 applied, the center portion of the substrate W is displaced and the value of the amount of displacement is positive and the upper limit value in the period from the point t3 to the point t4 in time. At the point t4 in time, the center portion of the substrate W is displaced such that the value of the amount of displacement is positive as shown in FIGS. 11 and 12. At the point t4 in time, the lower-surface brush operation driver 55a stops controlling the electropneumatic regulator.

At the point t2 in time, as shown in FIGS. 9 and 10, the lower-surface brush 51 comes into contact with the substrate W in the center region R2 in the lower-surface center region BC of the substrate W. Therefore, the center region R2 of the substrate W is cleaned.

At the point t3 in time, the lower-surface brush 51 comes into contact with the substrate W in the entire region R1 in the lower-surface center region BC of the substrate W. Therefore, at the point t3 in time, the entire region R1 (the lower-surface center region BC) of the substrate W is cleaned. In the period from the point t2 to the point t3 in time, the portion in which the lower-surface brush 51 and the substrate W come into contact with each other gradually spreads from the center region R2 to become the entire region R1.

At the point t4 in time, the lower-surface brush 51 comes into contact with the substrate W in the annular region R3 in the lower-surface center region BC of the substrate W. Therefore, the annular region R3 of the substrate W is cleaned. In the period from the point t3 to the point t4 in time, the portion in which the lower-surface brush 51 and the substrate W come into contact with each other is gradually decreased from the entire region R1 to become the annular region R3.

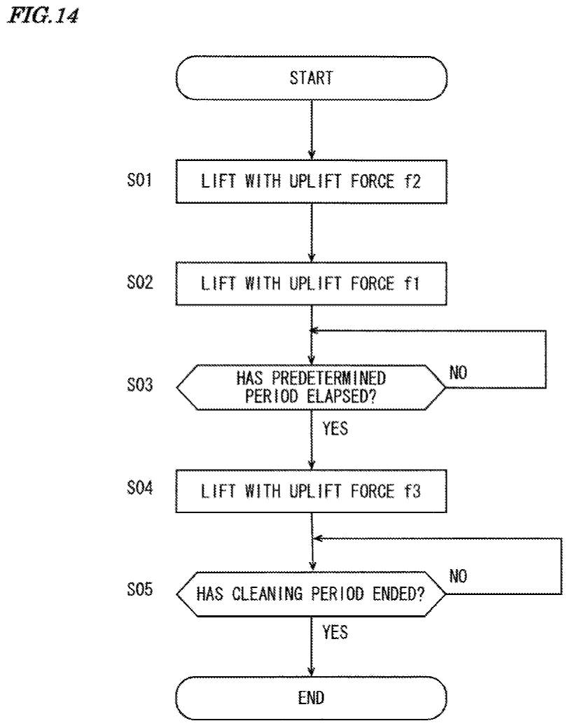

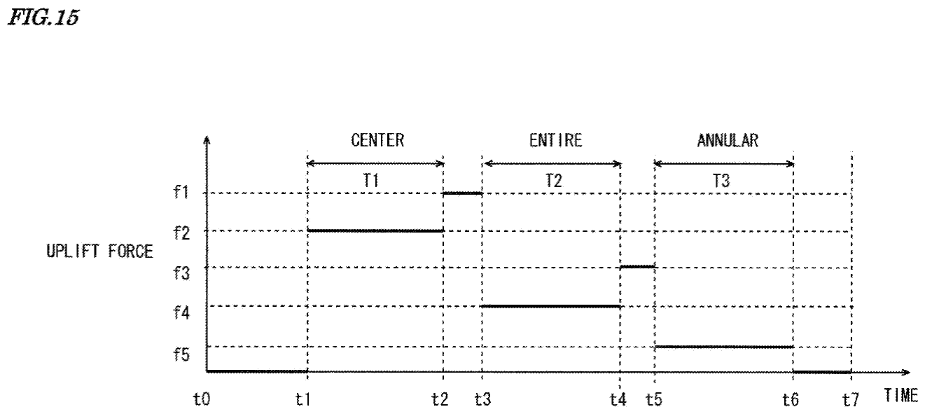

FIG. 14 is a flowchart showing one example of a flow of an uplift force control process. The uplift force control process is a process to be executed by the control device 9. With reference to FIG. 14, the control device 9 controls the lower-surface brush operation driver 55a to uplift the lower-surface brush 51 with the uplift force f2 (step S01). At this stage, as shown in FIGS. 9 and 10, the lower-surface brush 51 comes into contact with the substrate W in the center region R2 in the lower-surface center region BC of the substrate W. In the next step S02, the control device 9 uplifts the lower-surface brush 51 with the uplift force f1, and the process proceeds to the step S03. The uplift force f1 has a value larger than that of the uplift force f2. Therefore, the lower-surface brush 51 is lifted, and the center of the substrate W is uplifted by the lower-surface brush 51.

In the step S03, whether a predetermined period of time has elapsed since the start of uplifting of the lower-surface brush 51 with the uplift force f1 is determined. The predetermined period of time is a period of time required for the center portion of the substrate W to be moved to the reference position. The process waits until the predetermined period of time elapses (NO in the step S03). If the predetermined period of time has elapsed (YES in the step S03), the process proceeds to the step S04. In a case in which a displacement sensor for detecting the displacement of the center portion of the substrate W is provided, the displacement of the center portion of the substrate W may be detected based on the output of the displacement sensor. As shown in FIGS. 7 and 8, immediately before the process proceeds to the step S04, the lower-surface center region BC of the substrate W is located at the reference position, and the entire region R1 of the substrate W comes into contact with the lower-surface brush 51.

In the next step S04, the control device 9 uplifts the lower-surface brush 51 with the uplift force f3, and the process proceeds to the step S05. Therefore, the lower-surface brush 51 is lifted, and the center portion of the substrate W is uplifted by the lower-surface brush 51. In the stage where the process proceeds to the step S04, the center portion of the substrate W is displaced, and the value of the amount of displacement is positive. With the center portion of the substrate W being displaced and being located at a position higher than the reference position, the pressing forces applied to the substrate W by the pair of upper holding devices 10A, 10B are exerted in such a direction that the center portion of the substrate W is moved to a higher position. Therefore, the uplift force f3 is smaller than the uplift force f2.

In the step S05, whether the cleaning period has ended is determined. The process waits until the cleaning period ends (NO in the step S05). If the cleaning period ends (YES in the step S5), the process ends.

Although being moved from a position lower than the reference position to a position higher than the reference position by way of example in the present embodiment, the center portion of the substrate W may be moved from a position higher than the reference position to a position lower than the reference position.

### 4. Modified Example of Uplift Force Control

FIG. 15 is a time chart showing one example of the change of an uplift force in a modified example. In the time chart of FIG. 15, the ordinate indicates an uplift force, and the abscissa indicates time.

With reference to FIG. 15, at a point t0 in time before the cleaning of the lower-surface center region BC of the substrate W by the lower-surface brush 51 is started, the lower-surface brush operation driver 55a does not apply an uplift force to the lower-surface brush 51. At a point t1 in time before the cleaning of the lower-surface center region BC of the substrate W by the lower-surface brush 51 is started, the lower-surface brush operation driver 55a controls the electropneumatic regulator to apply an uplift force f2 to the lower-surface brush 51. Then, in a period T1 from the point t1 to a point t2 in time, the electropneumatic regulator is controlled such that an uplift force f1 is applied to the lower-surface brush 51. The uplift force f2 is defined by the resultant force of the gravity of the substrate W and the pressing forces with which the pair of upper holding devices 10A, 10B hold the substrate W. Specifically, the uplift force f2 has a predetermined value that causes the value of the amount of displacement of the center portion of the substrate W to be kept being the lower limit value. Therefore, in the period T1, as shown in FIGS. 9 and 10, the lower-surface brush 51 and the substrate W are in contact with each other with the value of the amount of displacement of the substrate W being the lower limit value. Therefore, in the period T1, the lower-surface brush 51 comes into contact with the substrate W in the center region R2 in the lower-surface center region BC of the substrate W. Therefore, the center region R2 of the substrate W is cleaned.

From the point t2 to a point t3 in time, the lower-surface brush operation driver 551 controls the electropneumatic regulator to apply the uplift force f1 to the lower-surface brush 51. The uplift force f1 has a value larger than that of the uplift force f2. With the center portion of the substrate W being displaced and being located at a position lower than the reference position, the pressing forces applied to the substrate W by the pair of upper holding devices 10A, 10B are exerted in such a direction that the center portion of the substrate W is moved to a lower position. Because the uplift force f1 is larger than the uplift force f2, the lower-surface brush 51 is lifted, and the center portion of the substrate W is uplifted, in the period from the point t2 to the point t3 in time. The uplift force f1 is defined such that, with the uplift force f1 applied, the center portion of the substrate W is located at the reference position in the period from the point t2 to the point t3 in time.

Then, in a period t2 from the point t3 to a point t4 in time, the electropneumatic regulator is controlled such that an uplift force f4 is applied to the lower-surface brush 51. With the center portion of the substrate W located at the reference position, an uplift force applied to the substrate W by the pair of upper holding devices 10A, 10B is not exerted in such a direction that the center portion of the substrate W is displaced in the upward-and-downward direction. Therefore, the uplift force f4 has a value smaller than that of the uplift force f2. Specifically, as shown in FIGS. 7 and 8, the uplift force f4 has a predetermined value that causes the center portion of the substrate W to be kept located at the reference position. Therefore, in the period T2, as shown in FIGS. 7 and 8, the center portion of the substrate W is not displaced. Therefore, in the period T2, the lower-surface brush 51 comes into contact with the substrate W in the entire region R1 in the lower-surface center region BC of the substrate W. Therefore, the entire region R1 of the substrate W is cleaned.

From the point t4 to a point t5 in time, the lower-surface brush operation driver 551 controls the electropneumatic regulator to apply an uplift force f3 to the lower-surface brush 51. The uplift force f3 has a value larger than that of the uplift force f4. With the center potion of the substrate W not displaced and with the value of the amount of displacement not being negative or positive, the pressing forces applied to the substrate W by the pair of upper holding devices 10A, 10B are not exerted in such a direction that the center portion of the substrate W is displaced. Because the uplift force f3 is larger than the uplift force f4, the lower-surface brush 51 is lifted, and the center portion of the substrate W is uplifted, in the period from the point t4 to the point t5 in time. The uplift force f3 is defined such that, with the uplift force f3 applied, the center portion of the substrate W is displaced and the value of the amount of displacement of the substrate W is positive and the upper limit value in the period from the point t4 to the point t5 in time.

Then, in a period T3 from the point t5 to a point t6 in time, the electropneumatic regulator is controlled such that an uplift force f5 is applied to the lower-surface brush 51. With the center portion of the substrate W being displaced and being located at a position higher than the reference position, the pressing forces applied to the substrate W by the pair of upper holding devices 10A, 10B are exerted in such a direction that the center portion of the substrate W is moved to a higher position. Therefore, the uplift force f5 has a value smaller than that of the uplift force f4. Specifically, the uplift force f5 has a predetermined value that causes the value of the amount of displacement of the center portion of the substrate W to be kept being the upper limit value. Therefore, in the period T3, as shown in FIGS. 11 and 12, the lower-surface brush 51 and the substrate W are in contact with each other with the value of the amount of displacement of the substrate W being the upper limit value. Therefore, in the period T3, the lower-surface brush 51 comes into contact with the substrate W in the annular region R3 in the lower-surface center region BC of the substrate W. Therefore, the annular region R3 of the substrate W is cleaned. At the point t6 in time, the lower-surface brush operation driver 55a stops controlling the electropneumatic regulator.

In the period T1, the lower-surface brush 51 is uplifted with the uplift force f2. In the period T2, the lower-surface brush 51 is uplifted with the uplift force f4. In the period T3, the lower-surface brush 51 is uplifted with the uplift force f5. Because the uplift force f2, the uplift force f4 and the uplift force f5 are different from one another, the period T1, the period T2 and the period T3 may be different from one another in accordance with the uplift force f2, the uplift force f4 and the uplift force f5. For example, a period can be determined based on the uplift force per unit area which is obtained based on an uplift force and a contact area.

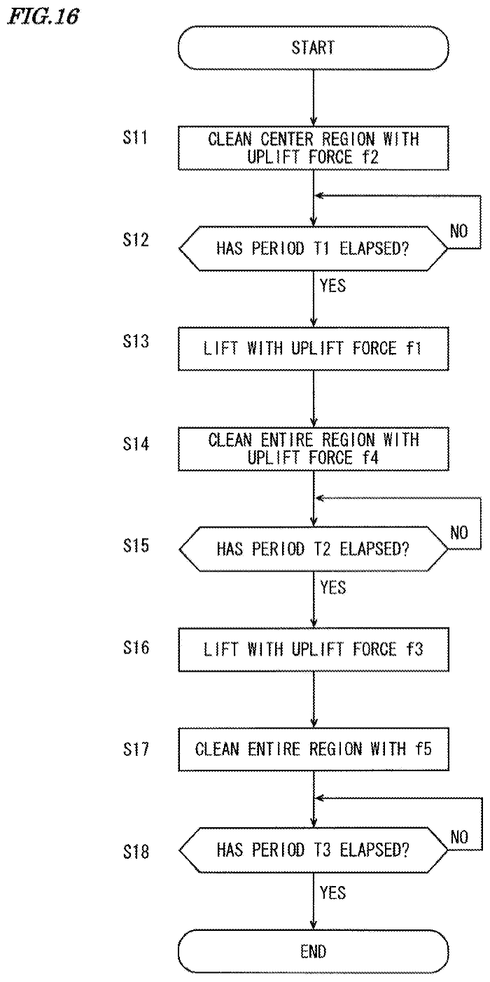

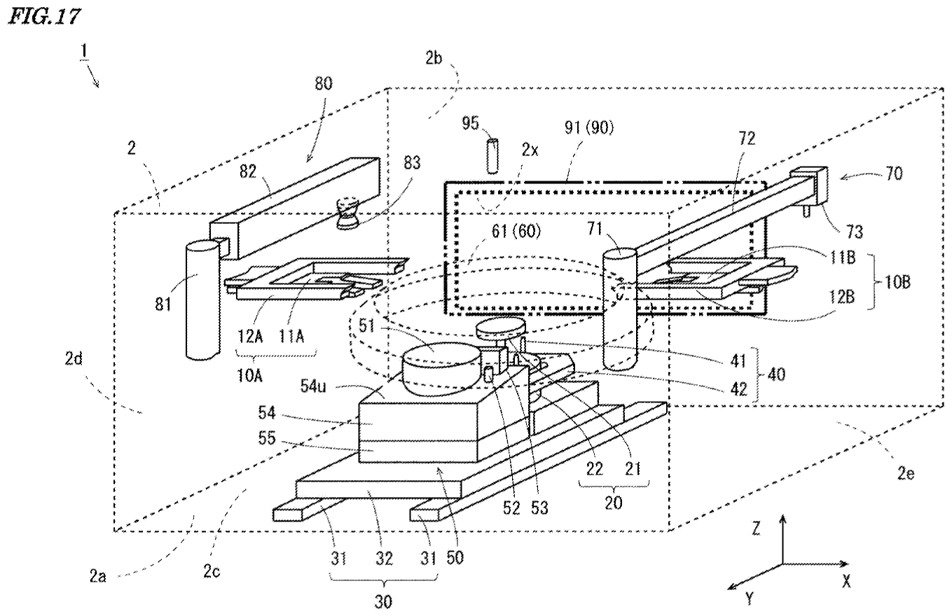

FIG. 16 is a flowchart showing one example of a flow of an uplift force control process in the modified example. With reference to FIG. 16, the control device 9 controls the lower-surface brush operation driver 55a to uplift the lower-surface brush 51 with the uplift force f2 and clean the center region (step S11). In this case, the center region R2 is cleaned with the value of the amount of displacement of the substrate W being the lower limit value. In the next step S12, whether the period T1 has elapsed is determined. The period T1 is predetermined as a period during which the center region R2 is cleaned. The process waits until the period T1 elapses since the start of the cleaning of the center region R2 (NO in the step S12). When the period T1 elapses (YES in the step S15), the process proceeds to the step S13.

In the step S13, the lower-surface brush 51 is uplifted with the uplift force f2, and the process proceeds to the step S14. Thus, the lower-surface brush 51 is lifted, and the center portion of the substrate W is lifted to the reference position. In the step S14, the lower-surface brush 51 is uplifted with the uplift force f1, and the entire region R1 is cleaned. Then, the process proceeds to the step S15. In the step S15, whether the period T2 has elapsed is determined. The period T2 is predetermined as a period during which the entire region R1 is cleaned. The process waits until the period T2 elapses since the start of the cleaning of the entire region R1 (NO in the step S15). When the period T2 elapses (YES in the step S15), the process proceeds to the step S13.

In the step S16, the lower-surface brush 51 is uplifted with the uplift force f3, and the process proceeds to the step S17. Thus, the lower-surface brush 51 is lifted, and the value of the amount of displacement of the substrate W is the upper limit value. In the step S17, the lower-surface brush 51 is uplifted with the uplift force f5, and the annular region R3 is cleaned. Then, the process proceeds to the step S18. In the step S18, whether the period T3 has elapsed is determined. The period T3 is predetermined as a period during which the annular region R3 is cleaned. The process waits until the period T3 elapses since the start of cleaning of the annular region R3 (NO in the step S17). When the period T3 elapses (YES in the step S17), the process ends.

### 5. Second Modified Example of Uplift Force Control

An uplift force applied to the lower-surface brush may be repeatedly varied. The cycle of the change of the uplift force shown in FIG. 13 can be repeated multiple times. Further, the change cycle of the uplift force shown in FIG. 13 shows a cycle in which the center region R2, the entire region R1 and the annular region R3 of the substrate W are cleaned in this order. However, it may a cycle in which the annular region R3, the entire region R1 and the center region R2 of the substrate W are cleaned in this order.

Further, the lifting force applied to the lower-surface brush may be gradually and repeatedly varied. The change cycle of the uplift force shown in FIG. 15 can be repeated multiple times. Further, the change cycle of the uplift force shown in FIG. 15 is a cycle in which the center region R2, the entire region R1 and the annular region R3 of the substrate W are cleaned in this order. However, it may a cycle in which the annular region R3, the entire region R1 and the center region R2 of the substrate W are cleaned in this order.

### 6. Effects

The substrate cleaning device 1 in the first embodiment changes an uplift force for uplifting the lower-surface brush 51 in the period during which the lower-surface brush 51 cleans the lower-surface center region BC of the substrate W. Therefore, the contact surface in which the lower-surface brush 51 and the substrate W come into contact with each other varies due to the displacement of the substrate W.

Further, because the uplift force of the lower-surface brush 51 is continuously changed, the rate of the displacement of the substrate W can be reduced.

Because the uplift force of the lower-surface brush 51 is changed gradually in the modified example, the center region R2, the entire region R1 and the annular region R3 of the substrate W can be separately cleaned. Therefore, it is possible to adjust the periods of time during which the center region R2, the entire region R1 and the annular region R3 are respectively cleaned, based on the magnitude of a force exerted between the lower-surface brush 51 and the substrate W and the area of the contact surface of the substrate W. Therefore, the lower-surface center region BC can be efficiently cleaned.

### Second Embodiment

### 1. Configuration of Substrate Cleaning Device in Second Embodiment

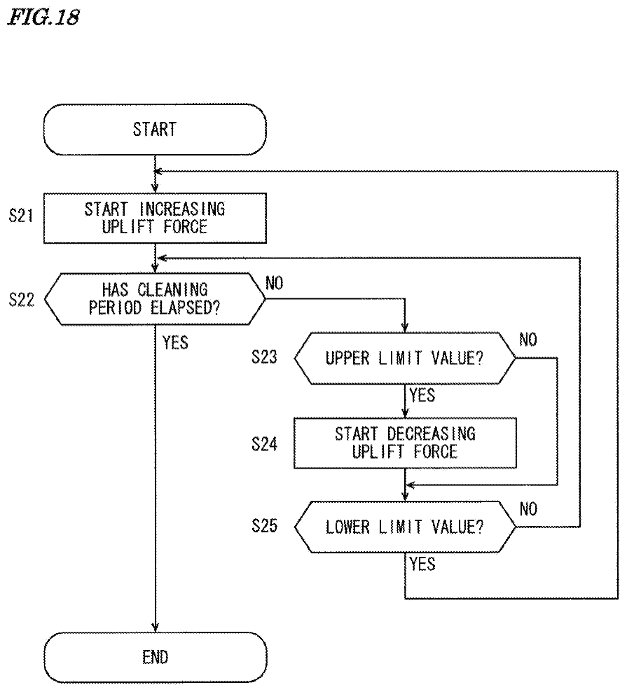

FIG. 17 is an external perspective view showing the inner configuration of a substrate cleaning device 1 in a second embodiment. With reference to FIG. 17, in regard to the substrate cleaning device 1 in the second embodiment, a displacement sensor 95 is added to the substrate cleaning device 1 shown in FIG. 2. The displacement sensor 95 is provided above the center of the substrate W held by the pair of upper holding devices 10A, 10B in the vertical direction. The displacement sensor 95 measures the distance to the center portion of the substrate W held by the pair of upper holding devices 10A, 10B. Therefore, the displacement sensor 95 detects the displacement of the center portion of the substrate W in the upward-and-downward direction (Z direction). Here, with the position at which the substrate W is held by the upper holding devices 10A, 10B as a reference position, an amount of displacement of the substrate W is indicated by the distance between the position of the center portion of the substrate W and the reference position in the vertical direction. The value of an amount of displacement is negative when the center portion of substrate W is located at a position lower than the reference position, and is positive when the center portion of the substrate W is located at a position higher than the reference position. Further, the value of the maximum amount of displacement that allows the center portion of the substrate W to be displaced to a position higher than the reference position is referred to as an upper limit value, and the value of the minimum amount of displacement that allows the center portion of the substrate W to be displaced to a position lower than the reference position is referred to as a lower limit value.

The substrate cleaning device 1 in the second embodiment varies an uplift force based on the output of the displacement sensor 95. Specifically, the uplift force is adjusted such that the value of the amount of displacement of the center portion of the substrate W falls between the upper limit value and the lower limit value.

### 2. Uplift Force Control for Lower-surface Brush in Second Embodiment

FIG. 18 is a flowchart showing one example of a flow of an uplift force control process in the second embodiment. With reference to FIG. 18, the control device 9 controls the lower-surface brush operation driver 55a to start increasing the uplift force (step S21), and the process proceeds to the step S22. The uplift force applied to the lower-surface brush 51 is gradually increased. Therefore, the lower-surface brush 51 starts to be lifted, and comes into contact with the lowermost end of the substrate W at a certain point in time. In this stage, cleaning of the center region R2 of the substrate W is started.

Further, when the uplift force is increased, the lower-surface brush 51 is lifted together with the substrate W. The area of the contact surface in which the substrate W comes into contact with the lower-surface brush 51 is gradually increased as the substrate W is lifted, and the entire region R1 of the substrate W comes into contact with the lower-surface brush 51. Further, when the lower-surface brush 51 is lifted together with the substrate W, the area of the contact surface in which the substrate W comes into contact with the lower-surface brush 51 is gradually decreased, and the annular region R3 of the substrate W comes into contact with the lower-surface brush 51. Further, when the lower-surface brush 51 is lifted together with the substrate W, the shape of the substrate W is changed, and the value of the amount of displacement of the center portion of the substrate W reaches the upper limit value.

In the step S22, whether a cleaning period that is predetermined as a period during which the lower-surface brush 51 cleans the substrate W has elapsed is determined. If the cleaning period has not elapsed (NO in the step S22), the process proceeds to the step S23. If the cleaning period has elapsed (YES in the step S22), the process ends.

In the step S23, whether the value of the amount of displacement of the substrate W is the upper limit value is determined. The amount of displacement of the substrate W is detected based on the output of the displacement sensor 95. If the value of the amount of displacement of the substrate W is the upper limit value, the process proceeds to the step S24. If not, the process proceeds to the step S25. In a case in which the process proceeds to the step S24, the contact surface in which the lower-surface brush 51 and the substrate W come into contact with each other is the annular region R3 shown in FIGS. 11 and 12.

In the step S24, the control device 9 controls the lower-surface brush operation driver 55a to start decreasing the uplift force, and the process proceeds to the step S25. Thus, the uplift force is decreased as the time elapses. When the uplift force is decreased, the lower-surface brush 51 is lowered together with the substrate W. In this stage, the shape of the substrate W is changed, the area of the contact surface in which the substrate W comes into contact with the lower-surface brush 51 is gradually increased, and the entire region R1 of the substrate W comes into contact with the lower-surface brush 51. Further, in the stage where the lower-surface brush 51 is lowered together with the substrate W, the shape of the substrate W is changed, and the area of the contact surface in which the substrate W comes into contact with the lower-surface brush 51 is gradually decreased, and the center region R2 of the substrate W comes into contact with the lower-surface brush 51.

In the step S25, whether the value of the amount of displacement of the substrate W is the lower limit value is determined. The amount of displacement of the substrate W is detected based on the output of the displacement sensor 95. If the value of the amount of displacement of the substrate W is the lower limit value, the process returns to the step S21. If not, the process returns to the step S22.

### 3. Effects

The substrate cleaning device 1 in the second embodiment has the similar effects as those of the substrate cleaning device 1 in the first embodiment. Further, the uplift force is changed such that the displacement of the substrate W detected by the displacement sensor 95 falls in the predetermined range. Therefore, the substrate W can be prevented from being damaged.

### OTHER EMBODIMENTS

(1) The substrate cleaning device 1 in each of the first embodiment and the second embodiment changes the force to be exerted between the substrate W and the lower-surface brush 51 by changing the uplift force applied to the lower-surface brush 51. Therefore, the force to be exerted between the substrate W and the lower-surface brush 51 is changed, so that the substrate W is deformed. The present invention is not limited to this. The force to be exerted between the substrate W and the lower-surface brush 51 may be changed by keeping of the uplift force applied to the lower-surface brush 51 constant and changing of the pressing forces applied to the substrate W by the pair of upper holding devices 10A, 10B. This can also deform the substrate W because the force to be exerted between the substrate W and the lower-surface brush 51 is changed.

(2) In each of the first and second embodiments, the uplift force applied to the lower-surface brush 51 is controlled such that the center portion of the substrate W is displaced and the value of the amount of displacement is between the upper limit value and the lower limit value by way of example. However, the uplift force applied to the lower-surface brush 51 may be controlled such that the center portion of the substrate W is displaced and located between a position at which the value of the amount of displacement is the lower limit value and the reference position.

### Correspondences Between Constituent Elements in Claims and Parts in Preferred Embodiments

In the following paragraphs, non-limiting examples of correspondences between various elements recited in the claims below and those described above with respect to various preferred embodiments of the present disclosure are explained. As each of various elements recited in the claims, various other elements having configurations or functions described in the claims can be also used.

In the above-mentioned embodiment, the substrate cleaning device 1 is an example of a substrate cleaning device, the pair of upper holding devices 10A, 10B are an example of a substrate holder, the lower-surface brush 51 is an example of a cleaner, the control device 9 is an example of a cleaning controller, and the displacement sensor 95 is an example of a displacement sensor.

1. A substrate cleaning device comprising:
a substrate holder that holds an outer peripheral end of a substrate;
a cleaner that comes into contact with a lower surface of the substrate to clean the lower surface of the substrate; and
a cleaning controller that changes an uplift force for uplifting the cleaner in a period during which the cleaner cleans a lower-surface center region of the substrate.

2. The substrate cleaning device according to claim 1, wherein the cleaning controller continuously changes the uplift force.

3. The substrate cleaning device according to claim 1, wherein the cleaning controller gradually changes the uplift force applied by the cleaner.

4. The substrate cleaning device according to claim 1, further comprising a displacement sensor that detects displacement of the substrate, wherein the cleaning controller changes the uplift force such that displacement of the substrate falls within a predetermined range.

5. A substrate cleaning device comprising:
a substrate holder that holds an outer peripheral end of a substrate;
a cleaner that comes into contact with a lower surface of the substrate to clean the lower surface of the substrate; and
a controller that changes a force exerted between the cleaner and the substrate in a period during which the cleaner cleans a lower-surface center region of the substrate.

6. The substrate cleaning device according to claim 5, further comprising a displacement sensor that detects displacement of the substrate, wherein the controller changes a force exerted between the cleaner and the substrate such that displacement of the substrate falls within a predetermined range.

7. A substrate cleaning method that is performed in a substrate cleaning device,
the substrate cleaning device comprising:
a substrate holder that holds an outer peripheral end of a substrate; and
a cleaner that comes into contact with a lower surface of the substrate to clean the lower surface of the substrate, and
the substrate cleaning method including a cleaning control step of changing an uplift force for uplifting the cleaner in a period during which the cleaner cleans a lower-surface center region of the substrate.

8. A substrate cleaning method that is performed in a substrate cleaning device,
the substrate cleaning device comprising:
a substrate holder that holds an outer peripheral end of a substrate; and
a cleaner that comes into contact with a lower surface of the substrate to clean the lower surface of the substrate, and
the substrate cleaning method including a control step of changing a force exerted between the cleaner and the substrate in a period during which the cleaner cleans a lower-surface center region of the substrate.

9. The substrate cleaning device according to claim 2, further comprising a displacement sensor that detects displacement of the substrate, wherein the cleaning controller changes the uplift force such that displacement of the substrate falls within a predetermined range.

10. The substrate cleaning device according to claim 3, further comprising a displacement sensor that detects displacement of the substrate, wherein the cleaning controller changes the uplift force such that displacement of the substrate falls within a predetermined range.
